(19) United States
(12) Patent Application Publication
(10) Pub. No.: US 2024/0145628 A1
(43) Pub. Date: May 2, 2024

(54) MANUFACTURING METHOD FOR EPITAXIAL SUBSTRATE, EPITAXIAL SUBSTRATE AND SEMICONDUCTOR STRUCTURE

(71) Applicant: ENKRIS SEMICONDUCTOR, INC., Suzhou (CN)

(72) Inventors: Liyang ZHANG, Suzhou (CN); Kai CHENG, Suzhou (CN)

(73) Assignee: ENKRIS SEMICONDUCTOR, INC., Suzhou (CN)

(21) Appl. No.: 18/489,665

(22) Filed: Oct. 18, 2023

(30) Foreign Application Priority Data
Nov. 1, 2022 (CN) 202211358271.5

(51) Int. Cl. H01L 33/16; H01L 33/00; H01L 33/20

(52) U.S. Cl. CPC H01L 33/16; H01L 33/0095; H01L 33/20

(57) ABSTRACT

Disclosed are a manufacturing method for an epitaxial substrate, an epitaxial substrate, and a semiconductor structure. The manufacturing method includes: patterning a substrate to form a trench; manufacturing a transition layer in the trench, and performing crystal plane transformation processing on the transition layer based on a shape of the trench, so as to transform the transition layer into a single crystal layer, where a surface, away from the substrate, of the single crystal layer is a (111) crystal plane. Based on different shapes of the trench on the substrate, the transition layer is controlled to obtain a single crystal layer of a specific crystal plane after the crystal plane transformation processing, and a surface, away from the substrate, of the single crystal layer, is a (111) crystal plane. The (111) crystal plane of the single crystal layer facilitates subsequent epitaxial manufacturing of a semiconductor structure.

### CROSS-REFERENCE TO RELATED APPLICATIONS

The present application claims priority to Chinese Patent Application No. 202211358271.5, filed on Nov. 1, 2022, which is hereby incorporated by reference in its entirety.

### TECHNICAL FIELD

The present disclosure relates to the field of semiconductor technologies, and in particular, to a manufacturing method for an epitaxial substrate, an epitaxial substrate, and a semiconductor structure.

### BACKGROUND

In the field of semiconductors, a common substrate of a GaN (gallium nitride)-based semiconductor device includes a silicon substrate, a silicon carbide, a sapphire, and the like. Compared with a silicon carbide substrate and a sapphire substrate, a silicon substrate has advantages of a better thermal conductivity, a better electrical conductivity, and a large size that can be made into, and the like. However, when the silicon substrate is applied to the GaN-based semiconductor device, a thermal mismatch and a lattice mismatch, between a silicon and a GaN-based material, cause cracking of a GaN-based semiconductor film, which makes it difficult to make a high-performance semiconductor device.

### SUMMARY

In view of this, the present disclosure provides a manufacturing method for an epitaxial substrate.

According to an aspect of the present disclosure, a manufacturing method for an epitaxial substrate is provided, which includes: providing a substrate, and patterning the substrate to form a trench; manufacturing a transition layer in the trench, and performing crystal plane transformation processing on the transition layer based on a shape of the trench, so as to transform the transition layer into a single crystal layer, where a surface, away from the substrate, of the single crystal layer is a (111) crystal plane.

Optionally, the trench includes a cross-section parallel to a plane where the substrate is located, and the performing crystal plane transformation processing on the transition layer based on a shape of the trench, includes: performing the crystal plane transformation processing on the transition layer, based on a shape of the cross-section.

Optionally, the crystal plane transformation processing includes at least high-temperature annealing processing.

Optionally, when the shape of the cross-section is a triangle or a hexagon, the transition layer is transformed into the single crystal layer by the high-temperature annealing processing.

Optionally, when the shape of the cross-section is a rectangle, the crystal plane transformation processing further includes alkaline solution processing, where the performing the crystal plane transformation processing on the transition layer, based on a shape of the cross-section, includes: performing the high-temperature annealing processing on the transition layer to obtain an original single crystal layer; and performing the alkaline solution processing on a surface, away from the substrate, of the original single crystal layer by using an alkaline solution, to obtain the single crystal layer.

Optionally, the surface, away from the substrate, of the original single crystal layer, is a (100) crystal plane.

Optionally, the high-temperature annealing processing is laser annealing processing.

Optionally, the single crystal layer is made of a single crystal silicon.

Optionally, the transition layer is made of an amorphous silicon or a polycrystalline silicon.

Optionally, the manufacturing a transition layer in the trench, and performing crystal plane transformation processing on the transition layer based on a shape of the trench, so as to transform the transition layer into a single crystal layer, includes: manufacturing the transition layer on a whole surface of the substrate, where the trench is filled with the transition layer; polishing the transition layer until the substrate is exposed; and performing the crystal plane transformation processing on the transition layer to transform the transition layer into the single crystal layer.

Optionally, the manufacturing a transition layer in the trench, and performing crystal plane transformation processing on the transition layer based on a shape of the trench, so as to transform the transition layer into a single crystal layer, includes: manufacturing the transition layer on a whole surface of the substrate, where the trench is filled with the transition layer; performing the crystal plane transformation processing on the transition layer to transform the transition layer into the single crystal layer; and polishing the single crystal layer until the substrate is exposed.

Optionally, the manufacturing method for an epitaxial substrate further includes: growing an epitaxial structure layer on a side, away from the substrate, of the single crystal layer.

### BRIEF DESCRIPTION OF THE DRAWINGS

FIGS. 1 to 3 are schematic flowcharts of manufacturing an epitaxial substrate according to an embodiment of the present disclosure.

FIG. 4 is a schematic structural diagram of an epitaxial substrate according to an embodiment of the present disclosure.

FIG. 5 is a top view structural diagram of an epitaxial substrate according to an embodiment of the present disclosure.

FIG. 6 is a top view structural diagram of an epitaxial substrate according to another embodiment of the present disclosure.

FIG. 7 is a top view structural diagram of an epitaxial substrate according to another embodiment of the present disclosure.

FIG. 8 is a schematic diagram of an intermediate structure according to an embodiment of the present disclosure.

FIG. 9 is a schematic diagram of an intermediate structure according to another embodiment of the present disclosure.

FIG. 10 is a schematic diagram of a semiconductor structure according to an embodiment of the present disclosure.

FIG. 11 is a schematic diagram of a semiconductor structure according to another embodiment of the present disclosure.

FIG. 12 is a schematic diagram of a semiconductor structure according to another embodiment of the present disclosure.

FIG. 13 is a schematic structural diagram of an epitaxial substrate according to another embodiment of the present disclosure.

FIG. 14 is a schematic structural diagram of an epitaxial substrate according to another embodiment of the present disclosure.

### DETAILED DESCRIPTIONS OF THE EMBODIMENTS

Technical solutions in embodiments of the present disclosure are described clearly and completely below with reference to the drawings of the embodiments of the present disclosure. Apparently, the described embodiments are only a part, but not all of the embodiments of the present disclosure. All other embodiments that may be obtained by those of ordinary skill in the art based on the embodiments in the present disclosure without any inventive efforts fall into the protection scope of the present disclosure.

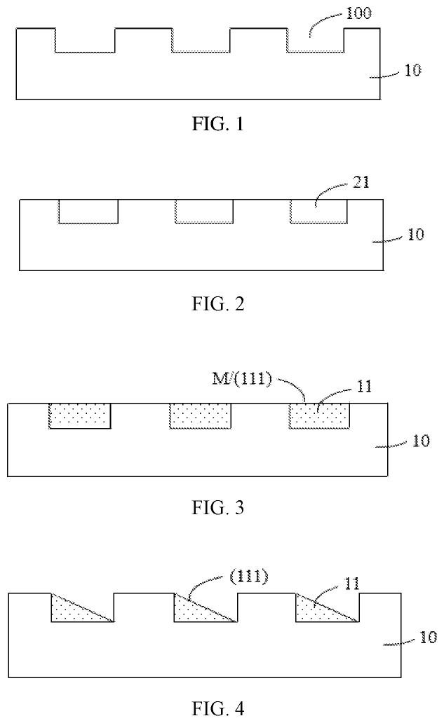

In view of this, an embodiment of the present disclosure provides a manufacturing method for an epitaxial substrate. FIG. 1 to FIG. 3 are schematic flowcharts of manufacturing an epitaxial substrate according to an embodiment of the present disclosure. As shown in FIG. 1 to FIG. 3, the method includes: providing a substrate 10 and patterning the substrate 10 to form at least one trench 100; manufacturing a transition layer 21 in the trench 100, and performing crystal plane transformation processing on the transition layer 21 based on a shape of the trench, so as to transform the transition layer 21 into a single crystal layer 11, where a surface, away from the substrate 10, of the single crystal layer 11 is a (111) crystal plane. Specifically, the shape of the trench may refer to a shape of a cross-section, parallel to a plane where the substrate 10 is located, of the trench, or as shown in FIG. 3, the shape of the trench may refer to a shape of the trench in a cross-section perpendicular to the substrate 10. Based on the shape of the trench, the transition layer 21 is transformed into the single crystal layer 11 by performing the crystal plane transformation processing, and the surface, away from the substrate 10, of the single crystal layer 11, is the (111) crystal plane. A single crystal layer of a specific crystal plane is manufactured based on a shape of a trench, and this method is simple and easy to operate.

Optionally, the substrate 10 is made of an amorphous material, such as a glass material or an organic polymer material, where the glass material is transparent, has a low cost and a simple production process, and may be used for manufacturing a Light Emitting Diode (LED) device epitaxially, so as to implement a transparent display. The substrate 10 may be made of a crystal material, such as a sapphire, or a quartz. As a substrate, the sapphire may be used to manufacture an LED device and a power device. A patterning method for forming the trench 100 on the substrate 10 may be dry etching, wet etching, or the like.

It should be noted that the transition layer 21 is manufactured in the trench 100, as shown in FIG. 2, the transition layer 21 is only located in the trench 100. Optionally, the transition layer 21 is manufactured on a whole surface of the substrate 10, and at least a part of the transition layer 21 is located in the trench 100. A manufacturing process of the transition layer 21 may be physical vapor deposition, chemical vapor deposition, or the like. Optionally, the transition layer 21 is made of an amorphous material or a polycrystalline material.

In an embodiment, as shown in FIG. 3, the trench 100 includes a cross-section M parallel to the plane where the substrate 10 is located, where the performing crystal plane transformation processing on the transition layer 21 based on a shape of the trench, includes: performing the crystal plane transformation processing on the transition layer 21, based on a shape of the cross-section M. The transition layer 21 is transformed into the single crystal layer 11, and a surface, away from the substrate 10, of the single crystal layer 11 is the (111) crystal plane.

It should be noted that, as shown in FIG. 3, an upper surface of the single crystal layer 11 is the (111) crystal plane. The upper surface is plotted as a plane for illustration only, and the upper surface of the (111) crystal plane of the single crystal layer 11 is not limited to be parallel to an upper surface of the substrate 10. FIG. 4 is a schematic structural diagram of an epitaxial substrate according to an embodiment of the present disclosure. As shown in FIG. 2 and FIG. 4, after the transition layer 21 is subjected to the crystal plane transformation processing, a single crystal layer 11 with a (111) crystal plane that is not parallel to the plane where the substrate 10 is located is obtained.

Specifically, the transition layer 21 is manufactured in the trench 100 of the substrate 10. Based on the shape of the cross-section M of the trench 100, in a process of the crystal plane transformation processing, the transition layer 21 is transformed into a single crystal layer with different crystal planes. After the crystal plane transformation processing is completed, a surface, away from the substrate 10, of the single crystal layer 11, is a (111) crystal plane, and the (111) crystal plane of the single crystal layer 11 facilitates subsequent epitaxial manufacturing of a semiconductor structure. Optionally, the shape of the cross-section M of the trench 100 may be a triangle or a hexagon, and the crystal plane transformation processing may be high-temperature annealing, so as to manufacture the single crystal layer 11 of the (111) crystal plane. Optionally, the shape of the cross-section M of the trench 100 may be a rectangle, and the crystal plane transformation processing includes high-temperature annealing processing and alkaline solution processing, to manufacture the single crystal layer 11 of the (111) crystal plane. A single crystal layer of a specific crystal plane is manufactured based on a shape of a cross-section M of a trench, and this method is simple and easy to operate.

In an embodiment, the crystal plane transformation processing includes at least high-temperature annealing processing.

Specifically, the crystal plane transformation processing may be a high-temperature annealing process, and the high-temperature annealing may transform the transition layer 21 made of an amorphous material or a polycrystalline material into a single crystal structure. The high-temperature annealing processing may be laser annealing processing. Compared with conventional high-temperature annealing, the laser annealing has advantages of fast heating up and local processing of a trench. Optionally, the laser annealing is performed by using nitrogen, argon, or oxygen. Optionally, a laser temperature range for the laser annealing may be 500-1400° C., and a laser energy density range for the laser annealing may be 400-3000 mJ/cm². Optionally, the laser annealing is performed on a transition layer by using Excimer Laser Annealing (ELA).

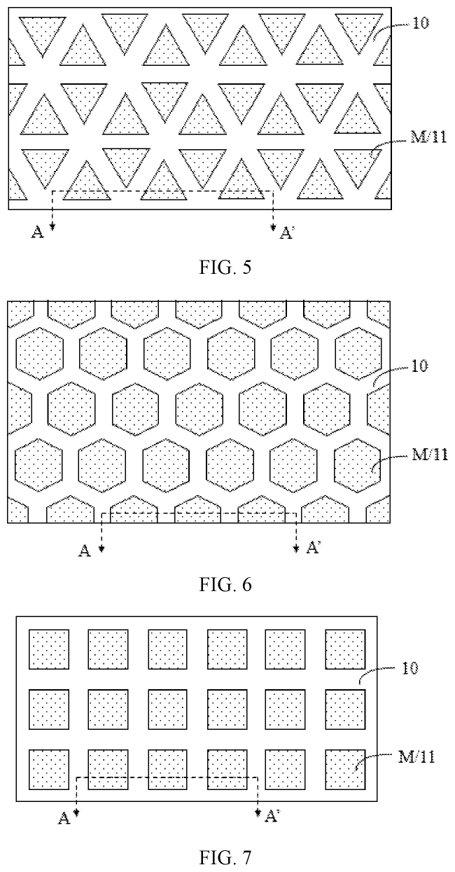

In an embodiment, as shown in FIG. 5 and FIG. 6, FIG. 5 is a top view structural diagram of an epitaxial substrate according to an embodiment of the present disclosure, and FIG. 6 is a top view structural diagram of an epitaxial substrate according to another embodiment of the present disclosure. When the shape of a cross-section M is a triangle or a hexagon, the transition layer 21 is transformed into the single crystal layer 11 by the high-temperature annealing processing, and the surface, away from a substrate 10, of the single crystal layer, is a (111) crystal plane.

Specifically, as shown in FIG. 5 and FIG. 6, a projection of the cross-section M of the trench 100 on the plane where the substrate 10 is located is a triangle or a hexagon. In a case that the shape of the cross-section M of the trench 100 is a triangle or a hexagon, in a high-temperature annealing process, the transition layer 21 is transformed into the single crystal layer 11 of a single crystal phase, and at an end of annealing, a surface, away from the substrate 10, of the single crystal layer 11 is transformed into a (111) crystal plane.

In an embodiment, as shown in FIG. 7, FIG. 7 is a top view structural diagram of an epitaxial substrate according to another embodiment of the present disclosure. When the shape of the cross-section M is a rectangle, the crystal plane transformation processing further includes alkaline solution processing, where the performing the crystal plane transformation processing on the transition layer 21, based on a shape of the cross-section M, includes: performing the high-temperature annealing processing on the transition layer 21 to obtain an original single crystal layer; and performing the alkaline solution processing on a surface, away from the substrate 10, of the original single crystal layer by using an alkaline solution, to obtain the single crystal layer 11. After the transition layer 21 being transformed into the original single crystal layer by performing the high-temperature annealing processing, the surface, away from the substrate 10, of the original single crystal layer is processed by using an alkaline solution, so that the surface of the original single crystal layer is a (111) crystal plane, that is, the single crystal layer 11 is obtained.

In some embodiments, the original single crystal layer and the single crystal layer 11 may have a same single crystal structure. A difference between the original single crystal layer and the single crystal layer 11 lies in that a crystal plane orientation of a surface, away from the substrate 10, of the original single crystal layer and a crystal plane orientation of a surface, away from the substrate 10, of the single crystal layer 11 are different. The difference is generated by the alkaline solution processing. Therefore, to a certain extent, the original single crystal layer and the single crystal layer 11 may correspond to different stages of a same material layer.

In an embodiment, as shown in FIG. 7, when the shape of the cross-section M is rectangular, the crystal plane transformation processing further includes the alkaline solution processing. After the transition layer 21 is transformed into the original single crystal layer by the crystal plane transformation processing, the surface, away from the substrate 10, of the original single crystal layer, is a (100) crystal plane, before the alkaline solution processing is performed.

Specifically, as shown in FIG. 7, a projection of the cross-section M of the trench 100 on the plane where the substrate 10 is located is a rectangle. In a case that the shape of the cross-section M of the trench 100 is a rectangle, the transition layer 21 is transformed into an original single crystal layer of a single crystal phase in a high-temperature annealing process, and at an end of annealing, the surface, away from the substrate 10, of the original single crystal layer is a (100) crystal plane. Then, the alkaline solution processing is performed on the original single crystal layer. The surface, away from the substrate 10, of the original single crystal layer is transformed from a (100) crystal plane into a (111) crystal plane, to obtain the single crystal layer 11.

It should be noted that FIG. 3 may be a structural diagram of an epitaxial substrate along the AA′ cross-section in FIG. 5 to FIG. 7.

It should be noted that, in a process that the surface, away from the substrate 10, of the original single crystal layer (or the single crystal layer 11), is transformed from the (100) crystal plane into the (111) crystal plane, an upper surface of the original single crystal layer (or the single crystal layer 11) shown in FIG. 3 may undergo a transformation from being parallel to the plane where the substrate 10 is located to have a non-zero included angle with the plane where the substrate 10 is located.

It should be noted that, as shown in FIG. 5 and FIG. 6, the single crystal layers 11 present a triangular dense arrangement and a hexagonal dense arrangement, respectively, thereby a space is effectively utilized. As shown in FIG. 7, the single crystal layer 11 is presented as a matrix arrangement in a horizontal direction and a vertical direction. Optionally, the single crystal layer 11 with a triangular or a hexagonal cross-section M is arranged in a matrix in the horizontal direction and the vertical direction.

In an embodiment, the single crystal layer 11 is made of a single crystal silicon.

In an embodiment, the transition layer 21 is made of an amorphous silicon or a polysilicon.

Specifically, the transition layer 21 is made of the amorphous silicon or the polycrystalline silicon. In the trench 100 of a specific shape, after the high-temperature annealing, the transition layer 21 is transformed into a single crystal layer 11 of a specific crystal plane, and the amorphous silicon or the polycrystalline silicon is transformed into a single crystal silicon. The (111) crystal plane of the single crystal silicon facilitates subsequent epitaxial manufacturing of a GaN-based semiconductor layer.

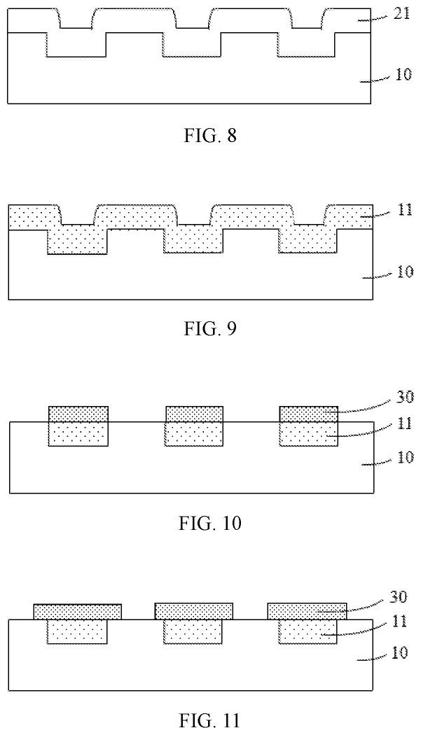

In an embodiment, FIG. 8 is a schematic diagram of an intermediate structure according to an embodiment of the present disclosure. As shown in a sequence of FIG. 1, FIG. 8, FIG. 2, and FIG. 3, the manufacturing a transition layer 21 in the trench 100, and performing crystal plane transformation processing on the transition layer 21 based on a shape of the trench, so as to transform the transition layer 21 into a single crystal layer 11, includes: as shown in FIG. 1 and FIG. 8, manufacturing the transition layer 21 on a whole surface of the substrate 10, where the trench 100 is filled with the transition layer 21; as shown in FIG. 2, polishing the transition layer 21 until the substrate 10 is exposed; and as shown in FIG. 3, performing the crystal plane transformation processing on the transition layer 21 to transform the transition layer 21 into the single crystal layer 11.

Specifically, as shown in FIG. 2, the transition layer 21 is first polished to a state that the transition layer 21 is only located in the trench 100 of the substrate 10, and then the high-temperature annealing processing is performed on the transition layer 21. After the crystal plane transformation processing, no other process is involved, so that the single crystal layer 11 whose surface is the (111) crystal plane may be obtained, and a crystal plane orientation is more complete and uniform.

It should be noted that the polishing may be Chemical Mechanical Polishing (CMP), and a surface of the transition layer 21 that is flat and has no scratches or impurities may be obtained.

In an embodiment, FIG. 9 is a schematic diagram of an intermediate structure according to another embodiment of the present disclosure. As shown in a sequence of FIG. 1, FIG. 8, FIG. 9, and FIG. 3, the manufacturing a transition layer 21 in the trench 100, and performing crystal plane transformation processing on the transition layer 21 based on a shape of the trench, so as to transform the transition layer 21 into a single crystal layer 11, includes: as shown in FIG. 1 and FIG. 8, manufacturing the transition layer 21 on a whole surface of the substrate 10, where the trench 100 is filled with the transition layer 21; as shown in FIG. 9, performing the crystal plane transformation processing on the transition layer 21 to transform the transition layer 21 into the single crystal layer 11; and as shown in FIG. 3, polishing the single crystal layer 11 until the substrate 10 is exposed.

Specifically, as shown in FIG. 9 and FIG. 3, the transition layer 21 manufactured on a whole surface is first transformed into the single crystal layer 11, and then the single crystal layer 11 of a whole surface is polished until the substrate 10 is exposed.

In some embodiments, as shown in FIG. 10 and FIG. 11, FIG. 10 is a schematic diagram of a semiconductor structure according to an embodiment of the present disclosure. FIG. 11 is a schematic diagram of a semiconductor structure according to another embodiment of the present disclosure. An epitaxial structure layer 30 is epitaxially grown on a side, away from the substrate 10, of the single crystal layer 11. A difference between FIG. 10 and FIG. 11 lies in that in FIG. 10, an orthographic projection area, on the plane where the substrate 10 is located, of the epitaxial structure layer 30, is consistent with an orthographic projection area, on the plane where the substrate 10 is located, of the single crystal layer 11, or an orthographic projection width, on the plane where the substrate 10 is located, of the epitaxial structure layer 30, is consistent with an orthographic projection width, on the plane where the substrate 10 is located, of the single crystal layer 11; and in FIG. 11, an orthographic projection area, on the plane where the substrate 10 is located, of the epitaxial structure layer 30, is greater than an orthographic projection area, on the plane where the substrate 30 is located, of the single crystal layer 11, or an orthographic projection width, on the plane where the substrate 10 is located, of the epitaxial structure layer 30, is greater than an orthographic projection width, on the plane where the substrate 30 is located, of the single crystal layer 11. In the two embodiments, the orthographic projection areas or the orthographic projection widths, on the plane where the substrate 10 is located, of the epitaxial structure layer 30 and the single crystal layer 11 may be controlled, by adjusting epitaxial growth conditions, for example, parameters such as an air pressure, an air flow, and the like.

Specifically, the epitaxial structural layer 30 may be a GaN-based material, such as a GaN, an InGaN, an AlGaN or an InAlGaN.

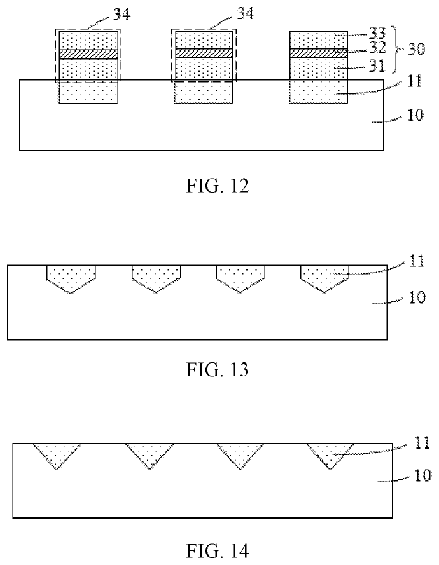

Optionally, as shown in FIG. 12, FIG. 12 is a schematic diagram of a semiconductor structure according to another embodiment of the present disclosure. The semiconductor structure is used as a light emitting device, and the epitaxial structure layer 30 includes a first semiconductor layer 31 and a second semiconductor layer 33 that have opposite conductivity types, and an active region 32 disposed between the first semiconductor layer 31 and the second semiconductor layer 33. The active region 32 includes a single quantum well or a multiple quantum well for emitting light. Based on an epitaxial substrate in this embodiment of the present disclosure, a light emitting device with an independent light emitting unit 34 may be manufactured relatively simply. It should be noted that a semiconductor film layer such as a nucleation layer or a buffer layer may be included between the first semiconductor layer 31 and the single crystal layer 11 (not shown in FIG. 11).

Optionally, FIG. 13 is a schematic structural diagram of an epitaxial substrate according to an embodiment of the present disclosure. FIG. 14 is a schematic structural diagram of an epitaxial substrate according to another embodiment of the present disclosure. As shown in FIG. 13 and FIG. 14, a lower surface of the single crystal layer 11 is not parallel to the plane where the substrate 10 is located, and the single crystal layer 11 may be a pyramid or a combination of a pyramid and a prism that are corresponding to the shape of the cross-section M. For example, when the shape of the cross-section M is a hexagon, the single crystal layer 11 in FIG. 13 is a combination of a hexagonal prism and a hexagonal pyramid, and a shape of the single crystal layer 11 in FIG. 14 is a hexagonal pyramid.

The present disclosure provides a manufacturing method for an epitaxial substrate, which includes: providing a substrate and patterning the substrate to form at least one trench; manufacturing a transition layer in the trench, and performing crystal plane transformation processing on the transition layer based on a shape of the trench, so as to transform the transition layer into a single crystal layer, where a surface, away from the substrate, of the single crystal layer is a (111) crystal plane. Based on different shapes of the trench on the substrate, the transition layer is controlled to obtain a single crystal layer of a specific crystal plane after the crystal plane transformation processing, and a surface, away from the substrate, of the single crystal layer, is a (111) crystal plane. The (111) crystal plane of the single crystal layer facilitates subsequent epitaxial manufacturing of a semiconductor structure.

It should be understood that the term “including” and its modification used in this disclosure are open-ended, that is, “including but not limited to”. Further, specific features, structures, materials, or features described may be incorporated in an appropriate manner in any one or more embodiments or examples. In addition, without being contradictory, those skilled in the art may combine and permutate different embodiments or examples described in this specification and features of different embodiments or examples. The foregoing descriptions are merely exemplary embodiments of the present disclosure, and are not intended to limit the present disclosure. Any modification, equivalent replacement, or the like made within a spirit and principles of the present disclosure shall be included in a protection scope of the present disclosure.

What is claimed is:

1. A manufacturing method for an epitaxial substrate, comprising:
patterning a substrate to form a trench;
manufacturing a transition layer in the trench, and performing crystal plane transformation processing on the transition layer based on a shape of the trench, so as to transform the transition layer into a single crystal layer, wherein a surface, away from the substrate, of the single crystal layer is a (111) crystal plane.

2. The method according to claim 1, wherein the trench comprises a cross-section parallel to a plane where the substrate is located, and the performing crystal plane transformation processing on the transition layer based on a shape of the trench, comprises:
performing the crystal plane transformation processing on the transition layer, based on a shape of the cross-section.

3. The method according to claim 2, wherein the crystal plane transformation processing comprises at least high-temperature annealing processing.

4. The method according to claim 3, wherein when the shape of the cross-section is a triangle or a hexagon, the transition layer is transformed into the single crystal layer by the high-temperature annealing processing.

5. The method according to claim 3, wherein when the shape of the cross-section is a rectangle, the crystal plane transformation processing further comprises alkaline solution processing, and the performing the crystal plane transformation processing on the transition layer, based on a shape of the cross-section, comprises:
performing the high-temperature annealing processing on the transition layer to obtain an original single crystal layer; and
performing the alkaline solution processing on a surface, away from the substrate, of the original single crystal layer by using an alkaline solution, to obtain the single crystal layer.

6. The method according to claim 5, wherein the surface, away from the substrate, of the original single crystal layer, is a (100) crystal plane.

7. The method according to claim 3, wherein the high-temperature annealing processing is laser annealing processing.

8. The method according to claim 7, wherein a laser temperature range of the laser annealing processing is 500-1400° C., and a laser energy density range of the laser annealing processing is 400-3000 mJ/cm².

9. The method according to claim 1, wherein the single crystal layer is made of a single crystal silicon.

10. The method according to claim 9, wherein the transition layer is made of an amorphous silicon or a polycrystalline silicon.

11. The method according to claim 1, wherein the manufacturing a transition layer in the trench, and performing crystal plane transformation processing on the transition layer based on a shape of the trench, so as to transform the transition layer into a single crystal layer, comprises:
manufacturing the transition layer on a whole surface of the substrate, wherein the trench is filled with the transition layer;
polishing the transition layer until the substrate is exposed; and
performing the crystal plane transformation processing on the transition layer to transform the transition layer into the single crystal layer.

12. The method according to claim 1, wherein the manufacturing a transition layer in the trench, and performing crystal plane transformation processing on the transition layer based on a shape of the trench, so as to transform the transition layer into a single crystal layer, comprises:
manufacturing the transition layer on a whole surface of the substrate, wherein the trench is filled with the transition layer;
performing the crystal plane transformation processing on the transition layer to transform the transition layer into the single crystal layer; and
polishing the single crystal layer until the substrate is exposed.

13. The method according to claim 1, further comprising:
growing an epitaxial structure layer on a side, away from the substrate, of the single crystal layer.

14. The method according to claim 13, wherein an orthographic projection area, on a plane where the substrate is located, of the epitaxial structure layer, is consistent with an orthographic projection area, on the plane where the substrate is located, of the single crystal layer, or an orthographic projection width, on the plane where the substrate is located, of the epitaxial structure layer, is consistent with an orthographic projection width, on the plane where the substrate is located, of the single crystal layer.

15. The method according to claim 13, wherein an orthographic projection area, on a plane where the substrate is located, of the epitaxial structure layer, is greater than an orthographic projection area, on the plane where the substrate is located, of the single crystal layer, or an orthographic projection width, on the plane where the substrate is located, of the epitaxial structure layer, is greater than an orthographic projection width, on the plane where the substrate is located, of the single crystal layer.

16. The method according to claim 13, wherein the epitaxial structure layer comprises a first semiconductor layer and a second semiconductor layer that have opposite conductivity types, and an active region disposed between the first semiconductor layer and the second semiconductor layer.

17. The method according to claim 2, wherein a lower surface of the single crystal layer is not parallel to the plane where the substrate is located, and the single crystal layer is a pyramid or a combination of a pyramid and a prism.

18. An epitaxial substrate, comprising:
a substrate, wherein a trench is disposed on a side of the substrate; and
a single crystal layer, wherein the single crystal layer is disposed in the trench, and a surface, away from the substrate, of the single crystal layer, is a (111) crystal plane.

19. A semiconductor structure, comprising:
a substrate, wherein a trench is disposed on a side of the substrate;
a single crystal layer, wherein the single crystal layer is disposed in the trench, and a surface, away from the substrate, of the single crystal layer, is a (111) crystal plane; and
an epitaxial structure layer, wherein the epitaxial structure layer is disposed on a side, away from the substrate, of the single crystal layer.

20. The semiconductor structure according to claim 19, wherein the epitaxial structure layer comprises a first semiconductor layer and a second semiconductor layer that have opposite conductivity types, and an active region disposed between the first semiconductor layer and the second semiconductor layer.
